(19) United States
(12) Patent Application Publication
(10) Pub. No.: US 2026/0308417 A1
(43) Pub. Date: Oct. 8, 2026

(54) CMP SLURRY COMPOSITION FOR POLISHING COPPER BARRIER LAYER

(71) Applicant: YCCHEM CO., LTD., Seongju-gun (KR)

(72) Inventors: Seung Hun LEE, Daegu (KR); Seung Hyun LEE, Daegu (KR); Seong Hwan KIM, Daegu (KR); Kyung II PARK, Seongju-gun (KR)

(21) Appl. No.: 18/879,092

(22) PCT Filed: Jun. 21, 2023
(86) PCT No.: PCT/KR2023/008568

§ 371 Date: Dec. 26, 2024

(30) Foreign Application Priority Data
Jul. 6, 2022 (KR) 10-2022-0083295

(51) Int. Cl. C09G 1/02; H10P 52/40

(52) U.S. Cl. CPC C09G 1/02; H10P 52/40

(57) ABSTRACT

The present invention relates to a CMP slurry composition for polishing a copper barrier layer, which is used for chemical mechanical planarization (CMP) of tantalum nitride or tantalum serving as a diffusion barrier film in the presence of an interconnect structure in integrated circuit devices. The CMP slurry composition according to the present invention includes abrasive particles, a heterocyclic compound, an organic acid, a surface protective agent, a nitrogen compound, a pH adjuster, and the balance of deionized water. The CMP slurry composition has good properties in terms of dispersibility and stability of abrasive particles, polishing selectivity, and reduction in dishing and defects.

### TECHNICAL FIELD

The present invention relates to a CMP slurry composition for polishing a copper barrier layer, which is used for chemical mechanical planarization (CMP) of tantalum nitride or tantalum serving as a diffusion barrier film in the presence of an interconnect structure in integrated circuit devices. The CMP slurry composition according to the present invention is a useful composition including abrasive particles, a heterocyclic compound, an organic acid, a surface protective agent, a nitrogen compound, a pH adjuster, and the balance of deionized water, and has good properties in terms of dispersibility and stability of abrasive particles, polishing selectivity, and reduction in dishing and defects, compared to typical CMP slurry compositions.

### Background Art

Recent advancements in semiconductor manufacturing processes have led to an increasing reliance on copper interconnects for forming integrated circuits in the semiconductor industry. These copper interconnects exhibit low electrical resistivity and high resistance to electromigration.

Due to many advantages in terms of efficiency, including high resistance to electromigration and low electrical resistivity, copper has been widely used as a primary electrical interconnect material for semiconductor integrated circuits such as miniaturized and highly integrated ULSI circuits.

However, due to difficulty of patterning copper through dry etching, there was a limitation in using copper for integrated circuits. To overcome this limitation, a method of forming copper interconnects using a dual damascene CMP process has been proposed. During the CMP process, copper forms a porous oxide film consisting of CuO, CuO₂, Cu(OH)₃, or the like, which contains copper oxide ions such as Cu⁺ or Cu²⁺.

However, copper is relatively weak compared to other materials, such as silicon (tetraethoxysilane (TEOS)) or tungsten, and is susceptible to electrochemical corrosion compared to tungsten. Thus, copper is more prone to dishing or erosion due to over-polishing and scratches, despite the ability to be polished at a high removal rate. In particular, due to the porous nature of a copper oxide film, components of polishing slurry and foreign matter such as oxides generated during a polishing process can penetrate the copper oxide film through pores thereof. This phenomenon can cause problems in subsequent processes such as photolithography. In particular, for highly integrated circuits, which consist of 6 or more layers depending on interconnect design, such a phenomenon can be a cause of severe defects, given that performance of the circuit is significantly affected by the degree of flatness of each layer.

Since copper is highly reactive with a wide range of dielectric materials, including silicon dioxide and low-K or doped versions thereof, a diffusion barrier layer is essential to prevent diffusion of copper into the underlying dielectric.

Typical barrier materials include tantalum, tantalum nitride, tantalum-silicon nitride, titanium, titanium nitride, titanium-silicon nitride, titanium-titanium nitride, titanium-tungsten, tungsten, tungsten nitride, and tungsten-silicon nitride.

In response to increasing demand for high-density integrated circuits, semiconductor manufacturers now fabricate integrated circuits containing multiple layers overlying a metal interconnect structure. During device fabrication, planarizing each interconnect layer improves packing density, process uniformity, and product quality and, most importantly, enables chipmakers to assemble multilayer integrated circuits. Chipmakers rely on chemical-mechanical planarization (CMP) as a relatively efficient means of producing substrates with flat surfaces.

The CMP process is typically carried out in two steps. First, the polishing process uses a “first-step” slurry specifically designed to rapidly remove copper.

After initial copper removal, a barrier material is removed using a “second-step” slurry. Typically, the second-step slurry is required to have good selectivity to remove the barrier material without adversely affecting the physical structure or electrical properties of an interconnect structure. Since alkaline polishing slurries generally have much higher Ta/TaN removal rates than acidic slurries, commercial second-step slurries typically have a neutral-to-basic pH. The need to preserve a metal overlying the barrier metal during the second step of polishing further highlights the benefits of using barrier metal polishing slurries with a neutral-to-basic pH. The removal rate of the metal is required to be very low to minimize dishing of the metal interconnect.

Consequently, in the chemical-mechanical planarization process, such a barrier slurry composition is required to achieve a high barrier removal rate, little or no post-polishing topography, no corrosion defects, and little or no scratch or etch defects. Depending on the types of abrasives, oxidants, or additives used therein, the slurry composition can effectively polish a metal insulating film, a diffusion barrier, or a metal layer at a desired removal rate while minimizing variance in critical parameters in semiconductor processes, such as surface imperfections, surface roughness, surface defects, erosion, corrosion, and the like.

Experiments conducted using typical CMP slurry compositions have revealed several problems, including low CMP throughput due to insufficient removal rates with respect to copper and tantalum nitride, deterioration of equipment performance and yield loss due to corrosion of copper materials; insufficient layer planarization; and dishing during polishing. Moreover, for a copper film polishing process required to achieve both an appropriate removal rate and a low surface defect rate, typical CMP slurry compositions resulted in prolonged polishing time or increased surface defects.

### PRIOR ART REFERENCE

(Patent Document 1) Korean Patent Registration No. 10-1465604
(Patent Document 2) Korean Patent Registration No. 10-1548715
(Patent Document 3) Korean Patent Registration No. 10-1698490
(Patent Document 4) Korean Patent Laid-open Publication No. 10-2021-0095548

### DISCLOSURE

### Technical Problem

It is one aspect of the present invention to solve the problems associated with typical CMP slurry compositions, such as low CMP throughput due to poor removal rates with respect to copper and tantalum nitride, degradation of equipment performance and yield loss due to corrosion of copper materials, insufficient layer planarization, and dishing during polishing.

It is another aspect of the present invention to provide a CMP slurry composition for polishing a copper barrier layer, which can achieve an appropriate removal rate in a copper film polishing process while significantly reducing dishing, corrosion, and defect density, compared to typical slurries.

It is a further aspect of the present invention to provide a CMP slurry composition for polishing a copper barrier layer, which can achieve enhanced step removal rates with respect to a silicon oxide film and a copper film during a copper CMP process, compared to typical slurries.

### Technical Solution

In accordance with an aspect of the present invention, there is provided a CMP slurry composition for polishing a copper barrier layer, including abrasive particles composed of colloidal silica, a heterocyclic compound, an organic acid, a surface protective agent, a nitrogen compound, a pH adjuster, and the balance of deionized water, wherein the polishing selectivity and removal rates with respect to a silicon oxide film, a tantalum film, and a copper film are adjusted through adjustment of the contents of the additives and the solvent and adjustment of the particle size of the colloidal silica.

In one embodiment, the colloidal silica may have a particle size of 75 nm to 95 nm.

In one embodiment, the heterocyclic compound may contain at least two nitrogen atoms and may include at least one selected from the group consisting of 1,2,4-H-triazole, 5-methylbenzotriazole, tetrazole, imidazole, 1,2-dimethylimidazole, benzotriazole (BTA), 1H-benzotriazole acetonitrile, and piperazine.

In one embodiment, the surface protective agent may include a nonionic surface protective agent selected from among polyvinyl alcohol (PVA), ethylene glycol (EG), glycerin, polyethylene glycol (PEG), polypropylene glycol (PPG), polyvinylpyrrolidone (PVP), and the like and an anionic surface protective agent selected from among ammonium dodecyl benzene sulfonate, ammonium polyoxyethylene alkyl sulfonate, ammonium polyoxyethylene alkyl aryl sulfonate, and the like. These may be used as a mixture thereof. More preferably, the surface protective agent includes a mixture of polyvinylpyrrolidone (PVP) as the nonionic surface protective agent and ammonium dodecyl benzene sulfonate as the anionic surface protective agent.

In one embodiment, the organic acid may include at least one carboxylic acid selected from the group consisting of citric acid, glutaric acid, malic acid, maleic acid, oxalic acid, phthalic acid, succinic acid, tartaric acid, and acetic acid. In addition, the organic acid may include at least one amino acid selected from the group consisting of nitrilotriacetic acid (NTA), iminodiacetic acid (IDA), methyl iminodiacetic acid (MIDA), hydroxyethyl iminodiacetic acid (HIDA), diethylenetriamine pentaacetic acid (DTPA), ethylenediamine tetraacetic acid (EDTA), n-hydroxyethyl ethylenediamine tetraacetic acid (HEDTA), methyl ethylenediamine tetraacetic acid (MEDTA), and triethylene tetraamine hexaacetic acid (TTHA).

In one embodiment, the antioxidant may include at least one selected from the group consisting of ascorbic acid, L(+)-ascorbic acid, isoascorbic acid, ascorbic acid derivatives, gallic acid, formamidine sulfinic acid, uric acid, tartaric acid, and cysteine.

In one embodiment, the pH adjuster may serve to adjust the pH of the slurry composition to a basic range and may include KOH, NH₄OH, NaOH, TMAH, TBAH, KNO₃, NH₄NO₃, HNO₃, and mixtures thereof. Since the pH of the slurry composition is closely related to stability of the abrasive particles and a polishing rate of the slurry composition, it is necessary to precisely adjust the pH of the slurry composition.

In one embodiment, the CMP slurry composition may include 13 wt % to 15 wt % of the abrasive particles composed of colloidal silica, abrasive particles, the heterocyclic compound, the organic acid, the surface protective agent, the nitrogen compound, the pH adjuster, and the balance of deionized water based on the total weight of the slurry composition.

In one embodiment, the CMP slurry composition may have a pH of 9 to 12.

In one embodiment, the CMP slurry composition may simultaneously polish two or more polishing target films selected from a silicon oxide film, a tantalum film, and a copper film.

In one embodiment, the CMP slurry composition may have a polishing selectivity ratio of 1:1 to 4:0.5 to 1 with respect to a tantalum nitride (TaN) film, a silicon oxide film, and a copper film.

### Advantageous Effects

A CMP slurry composition for polishing a copper barrier layer according to embodiments of the present invention can effectively remove step height of a silicon oxide film and a copper film, thereby ensuring improved productivity.

In addition, the CMP slurry composition for polishing a copper barrier layer according to the embodiments of the present invention can minimize dishing, corrosion, and defects of a copper film layer during a polishing process, thereby enabling efficient formation of a highly reliable and high-performance copper interconnect for semiconductor device layers and thus significantly contributing to production of a high-performance semiconductor device.

### BEST MODE

Generally, the terminology used herein is well-known and commonly used in the art to which the present invention pertains. In addition, unless otherwise defined, technical and scientific terms as used herein have a meaning generally understood by those skilled in the art.

In addition, it will be understood that the terms “includes”, “comprises”, “including”, and/or “comprising” when used in this specification, specify the presence of stated features, steps, operations, elements, and/or components, but do not preclude the presence or addition of one or more other features, steps, operations, elements, components, and/or groups, unless the context clearly indicates otherwise.

Generally, after removal of overburden copper in step 1 of a CMP process, a polished wafer surface exhibits local and global non-uniformity in flatness due to differences in step height at different locations. Low-density features tend to have high copper step heights, while high-density features tend to have low step heights.

Due to differences in step height after step 1, a step 2 CMP slurry having selective removal rates with respect to copper and oxide is highly desirable.

Herein, “selectivity ratio” refers to a ratio of the removal rate of one material to the removal rate of another material under the same polishing conditions.

In step 2 of a CMP process for patterned wafers, a barrier CMP slurry preferably provides one or more of the following: desirable removal rates with respect to various types of films, low within-wafer non-uniformity (WIW NU), minimal residues on a polished wafer after the CMP process, and polishing selectivity with respect to various target layers.

A specific featured distortion unsuitable for semiconductor manufacturing is damage to copper vias or metal lines caused by chemical components interacting therewith and further corrosion thereof during the CMP process. Therefore, it is crucial to incorporate a corrosion inhibitor into the barrier CMP slurry to reduce further corrosion of the copper vias or trenches and defects therein during the CMP process.

Chemical reactions of the barrier CMP slurry in step 2 of the CMP process include oxidation reactions induced by an oxidant used in the CMP slurry, for example, H₂O₂. Surfaces of metals including copper lines, vias, or trenches and a barrier material such as tantalum (Ta) are oxidized to form respective metal oxide films thereof.

Typically, copper is oxidized to a mixture of cuprous oxide or cupric oxide, and Ta is oxidized to Ta₂O₅. To enhance removal rates of copper lines, vias, or trenches and a barrier layer or barrier film, a chelating agent, a ligand, or other chemical additives capable of forming a chemical bond with copper cations and tantalum cations may be used in the barrier CMP slurry to promote dissolution of the resulting copper oxide and tantalum oxide.

Therefore, the objective of the present invention is to provide a CMP slurry composition that can significantly reduce corrosion or defects encountered in copper CMP processes and can provide significantly enhanced removal rates with respect to silicon oxide, copper, and tantalum films, compared to typical slurries.

A CMP slurry composition for polishing a copper barrier layer according to the present invention includes abrasive particles composed of colloidal silica, a heterocyclic compound, an organic acid, a surface protective agent, a nitrogen compound, a pH adjuster, and the balance of deionized water.

Herein, “colloidal silica” refers to a colloidal solution in which nanoscale silica particles are stably dispersed in a solvent without sedimentation. To achieve an appropriate balance between scratch reduction and removal rate, the colloidal silica preferably has a particle size of 75 nm to 95 nm, more preferably 80 nm to 90 nm.

If the particle size of the colloidal silica is less than 75 nm, film removal rates can be reduced, resulting in increased process time, whereas, if the particle size of the colloidal silica exceeds 95 nm, the colloidal silica can cause severe scratching.

Preferably, the colloidal silica is present in an amount of 13 wt % to 15 wt % based on the total weight of the slurry composition.

If the content of the colloidal silica is less than 13 wt %, film removal rates can be reduced due to insufficient solid content, whereas, if the content of the colloidal silica exceeds 15 wt %, aggregation of the abrasive particles can occur due to excessive content thereof.

In the CMP slurry composition according to one embodiment of the present invention, the heterocyclic compound contains at least two nitrogen atoms and may be selected from the group consisting of 1,2,4H-triazole, 5-methylbenzotriazole, tetrazole, imidazole, 1,2-dimethylimidazole, benzotriazole (BTA), 1H-benzotriazole acetonitrile, and piperazine. The heterocyclic compound as a corrosion inhibitor may be present in an amount of 0.005 wt % to 0.5 wt % in the slurry composition in terms of corrosion inhibition, removal rate, and stability of the slurry composition.

If the content of the corrosion inhibitor is less than 0.005 wt %, it can be impossible to control polishing of a copper film, resulting in dishing, whereas, if the content of the corrosion inhibitor exceeds 0.5 wt %, a copper film removal rate can be reduced and residues can remain on a surface of the copper film.

The CMP slurry composition according to the present invention includes the nitrogen compound, which functions as a pH adjuster, as a tantalum nitride removal rate enhancer. Nitrogen compounds are used as etching agents for tantalum nitride or titanium nitride and are effective in removing tantalum during a CMP process.

The nitrogen compound used in the present invention may include potassium nitrate (KNO₃), nitric acid (HNO₃), ammonium nitrate (NH₄NO₃), iron nitrate (Fe(NO₃)₂), and copper nitrate (Cu(NO₃)₂). These may be used as a mixture thereof. Typically, titanium nitride and tantalum nitride are relatively stable, are easily etched by a mixture of hydrofluoric acid and nitric acid, and react slowly with bases and aqua regia. The nitrogen compound may be present in an amount of about 0.05 wt % to about 10 wt %, preferably about 0.1 wt % to about 1 wt %, in the CMP slurry composition.

The surface protective agent used in the present invention may include a nonionic surface protective agent selected from among polyvinyl alcohol (PVA), ethylene glycol (EG), glycerin, polyethylene glycol (PEG), polypropylene glycol (PPG), polyvinylpyrrolidone (PVP), and the like and an anionic surface protective agent selected from among ammonium dodecyl benzene sulfonate, ammonium polyoxyethylene alkyl sulfonate, ammonium polyoxyethylene alkyl aryl sulfonate, and the like. These may be used as a mixture thereof. More preferably, the surface protective agent includes a mixture of polyvinylpyrrolidone (PVP) as the nonionic surface protective agent and ammonium dodecyl benzene sulfonate as the anionic surface protective agent.

The nonionic surface protective agent contains at least one functional group having affinity for the abrasive particles and is strongly and sustainably adsorbed onto the surface of the abrasive particles in solution phase, thereby increasing the size of the particles. Accordingly, the nonionic surface protective agent serves to ensure an enhanced removal rate with respect to a silicon oxide film. Furthermore, the nonionic surface protective agent can ensure dispersion stability of the particles due to steric repulsion force thereof. If the content of the surface protective agent is less than 0.15 wt % based on the total weight of the slurry composition, the particles can undergo rapid sedimentation due to reduction in dispersibility thereof, resulting in sedimentation of the particles during transport of an abrasive solution, making it difficult to uniformly supply an abrasive agent. Conversely, if the content of the surface protective agent exceeds 1.0 wt %, a thick surface protective agent layer acting as a cushion can be formed around the abrasive particles, hindering contact between the surface of the abrasive agent and a polishing target surface, causing reduction in removal rate with respect to the target surface.

The surface protective agent also serves to protect a surface of a wafer from residues on a polishing pad, metal residues, or organic residues during the polishing process, thereby reducing defects on the wafer. In particular, when used in combination with an anionic ammonium sulfonate derivative, the surface protective agent can further reduce defects by removing various residues from the wafer surface. Preferably, the surface protective agent is present in an amount of about 0.15 wt % to about 1.0 wt %, more preferably about 0.3 wt % to about 0.8 wr %, in the slurry composition.

The CMP slurry composition according to the present invention includes the organic acid to adjust a copper removal rate relative to a barrier metal removal rate.

The organic acid inhibits re-adsorption of copper oxide onto a copper layer, which is a polishing target, by forming a chelate with the copper oxide, thereby increasing the copper removal rate while reducing surface defects. Selective addition of organic acids to the slurry composition depending on the types of target metal components enables further improvement in CMP planarization of a dielectric/metal complex structure.

In this way, it is possible to increase both an erosion rate of a metal phase and selectivity of removal of the metal phase relative to removal of a dielectric phase, thereby ensuring a more efficient planarization process.

The organic acid used in the present invention may include a carboxylic acid and an amino acid. First, the carboxylic acid may include at least one selected from the group consisting of citric acid, glutaric acid, malic acid, maleic acid, oxalic acid, phthalic acid, succinic acid, tartaric acid, and acetic acid.

Second, the amino acid may include at least one selected from the group consisting of nitrilotriacetic acid (NTA), iminodiacetic acid (IDA), methyl iminodiacetic acid (MIDA), hydroxyethyl iminodiacetic acid (HIDA), diethylenetriamine pentaacetic acid (DTPA), ethylenediamine tetraacetic acid (EDTA), N-hydroxyethyl ethylenediamine tetraacetic acid (HEDTA), methyl ethylenediamine tetraacetic acid (MEDTA), and triethylene tetraamine hexaacetic acid (TTHA).

The organic acid may be present in an amount of 0.05 wt % to 5 wt % based on the total weight of the slurry composition. Preferably, the organic acid is present in an amount of 0.1 wt % to 3 wt % based on the total weight of the slurry composition. More preferably, the organic acid is present in an amount of 0.1 wt % to 1 wt % based on the total weight of the slurry composition. If the content of the organic acid is excessively low, the organic acid cannot provide the intended effects as a chelating agent, whereas, if the content of the organic acid is excessively high, an excess of the chelating agent can be wasted.

In a preferred embodiment of the present invention, the antioxidant includes at least one selected from the group consisting of ascorbic acid, L (+)-ascorbic acid, isoascorbic acid, ascorbic acid derivatives, gallic acid, formamidine sulfinic acid, uric acid, tartaric acid, and cysteine. The antioxidant may be present in an amount of 0.05 wt % to 1 wt % based on the total weight of the slurry composition. Preferably, the antioxidant is present in an amount of 0.1 wt % to 0.5 wt % based on the total weight of the slurry composition. More preferably, the antioxidant is present in an amount of 0.2 wt % to 0.3 wt % based on the total weight of the slurry composition. If the content of the antioxidant is excessively low, the antioxidant cannot provide the effect of preventing oxidation of metals, whereas, if the content of the antioxidant is excessively high, an excess of the antioxidant can be wasted or can remain on a wafer surface, causing defects.

In one embodiment of the present invention, the CMP slurry composition preferably has a pH of 9 to 12 to ensure stability of the slurry composition. If the pH of the slurry composition is less than 9, this can cause aggregation of the colloidal silica particles and failure to achieve a stable removal rate, whereas, if the pH of the slurry composition exceeds 12, this can cause failure to achieve a stable removal rate.

To adjust the pH of the slurry composition to the above range, a basic substance such as KOH, NH₄OH, NaOH, TMAH, TBAH, KNO₃, and NH₄NO₃ may be used. These may be used alone or as a mixture thereof. Since the pH of the slurry composition is closely related to stability of the abrasive particles within the slurry composition and the removal rate of the slurry composition, precise pH adjustment is essential.

In the CMP slurry composition according to one embodiment of the present invention, a solvent is used to adjust film removal rates through adjustment of the concentration of the slurry composition. The solvent may include deionized water, water, and the like, preferably deionized water.

A polishing target film of the slurry composition may include a copper-containing film.

In addition, the slurry composition may polish the copper-containing film, a thin barrier film selected from the group consisting of titanium (Ti), tantalum (Ta), ruthenium (Ru), molybdenum (Mo), cobalt (Co), and gold (Au), or an oxide film used as a semiconductor insulating film, at a desired removal rate. Accordingly, the slurry composition may have a high polishing selectivity ratio of the polishing target film to other thin films.

Next, the present invention will be described in more detail with reference to some examples. However, it should be noted that these examples are provided for illustration only and are not to be construed in any way as limiting the present invention.

### MODE FOR INVENTION

### Examples 1 to 7 and Comparative Examples 1 and 2

Slurry compositions for polishing a copper barrier layer were prepared according to the formulations shown in Table 1.

In all compositions, colloidal silica having a particle size of 90 nm was used as abrasive particles and the content of the colloidal silica was fixed at 13 wt %. In all compositions, KOH was used as a pH adjuster and KNO₃ was used as a nitrogen compound, each in an amount of 0.5 wt %. In addition, 0.2 wt % of ascorbic acid was used as an antioxidant.

TABLE 1

| | Particle | Heterocyclic | | | | | | | | | |
|---|---|---|---|---|---|---|---|---|---|---|---|
| | size of | compound | | Organic acid | | | | Surface protective agent | | | |
| | silica | | Cont. | | Cont. | | Cont. | | Cont. | | Cont. |
| | (nm) | Mat. | (wt %) | Mat. | (wt %) | Mat. | (wt % ) | Mat. | (wt %) | Mat. | (wt %) |
| Example | 90 | BTA | 0.1 | | | AA | 0.06 | | | PVP | 0.15 |
| 1 | | | | | | | | | | | |
| Example | 90 | BTA | 0.1 | IDA | 0.1 | AA | 0.06 | ADBS | 0.1 | PVP | 0.2 |
| 2 | | | | | | | | | | | |
| Example | 90 | BTA | 0.1 | IDA | 0.1 | AA | 0.06 | ADBS | 0.3 | PVP | 0.2 |
| 3 | | | | | | | | | | | |
| Example | 90 | BTA | 0.1 | IDA | 0.1 | AA | 0.06 | ADBS | 0.5 | PVP | 0.2 |
| 4 | | | | | | | | | | | |
| Example | 90 | BTA | 0.1 | IDA | 0.1 | AA | 0.06 | ADBS | 0.5 | PVP | 0.3 |
| 5 | | | | | | | | | | | |
| Example | 90 | BTA | 0.1 | IDA | 0.5 | AA | 0.06 | ADBS | 0.5 | PVP | 0.3 |
| 6 | | | | | | | | | | | |
| Example | 90 | BTA | 0.1 | IDA | 1.0 | AA | 0.06 | ADBS | 0.5 | PVP | 0.3 |
| 7 | | | | | | | | | | | |
| Comp. | 90 | BTA | 0.1 | | | | | | | | |
| Example | | | | | | | | | | | |
| 1 | | | | | | | | | | | |
| Comp. | 90 | BTA | 0.02 | | | | | | | | |
| Example | | | | | | | | | | | |
| 2 | | | | | | | | | | | |

BTA: Benzotriazole
IDA: Iminodiacetic acid
AA: Acetic acid
ADBS: Ammonium dodecyl benzene sulfonate
PVP: Polyvinylpyrrolidone

### Experimental Examples 1 to 7 and Comparative Experimental Examples 1 and 2

Removal rate and dishing were measured for each of the slurry compositions of Examples 1 to 7 and Comparative Examples 1 and 2 and results are presented in Table 2 as Experimental Examples 1 to 7 and Comparative Experimental Examples 1 and 2.

### [Polishing Conditions]

Polishing equipment: 12 inch (300 mm) CMP equipment (AP-300, CTS Co., Inc.)

Polishing pad: IC1010 (Dow Chemical)

Platen speed: 103 rpm

Head speed: 97 rpm

Flow rate: 300 cc/min

Pressure: 2.2 psi

Cu and Ta removal rates were determined using a 4-point probe (CMT-SR 5000, AIT Co., Ltd) after polishing with a 12-inch (300 mm) CMP equipment.

A PTEOS (oxide film) removal rate was determined using an Atlas system (Nanometrics Inc.) by measuring a change in thickness before and after CMP.

Polishing selectivity ratio was calculated from the measured removal rate of each film.

Polishing selectivity ratio of silicon oxide film to tantalum nitride (TaN) film=Removal rate of silicon oxide film/Removal rate of tantalum nitride (TaN) film

Polishing selectivity ratio of copper (Cu) film to tantalum nitride (TaN) film=Removal rate of copper (Cu) film/Removal rate of tantalum nitride (TaN) film

Dishing was determined by measuring the thickness of each film using a transmission electron microscope (JEM-2000, JEOL Ltd.).

Cu dishing=(Cu edge thickness)-(Cu center thickness)

Ox dishing=(Ox edge thickness)-(Ox center thickness)

TABLE 2

| | Removal rate | | | Selectivity | | |
|---|---|---|---|---|---|---|
| | (Å/min) | | | ratio | | |
| | | | Silicon | Silicon | | Dishing |
| | | | oxide | oxide | Cu/ | (Å) |
| | Cu | TaN | film | film/TaN | TaN | 1-1 μm |
| Experimental | 157 | 215 | 750 | 3.49 | 0.73 | 37 |
| Example 1 | | | | | | |
| Experimental | 162 | 320 | 815 | 2.55 | 0.51 | 30 |
| Example 2 | | | | | | |
| Experimental | 182 | 320 | 830 | 2.59 | 0.57 | 20 |
| Example 3 | | | | | | |
| Experimental | 200 | 325 | 820 | 2.52 | 0.62 | 17 |
| Example 4 | | | | | | |
| Experimental | 205 | 323 | 970 | 3.00 | 0.63 | 16 |
| Example 5 | | | | | | |
| Experimental | 214 | 310 | 915 | 2.95 | 0.69 | 17 |
| Example 6 | | | | | | |
| Experimental | 215 | 320 | 961 | 3.00 | 0.67 | 19 |
| Example 7 | | | | | | |
| Comparative | 107 | 260 | 498 | 1.92 | 0.41 | 69 |
| Experimental | | | | | | |
| Example 1 | | | | | | |
| Comparative | 127 | 295 | 578 | 1.96 | 0.43 | 118 |
| Experimental | | | | | | |
| Example 2 | | | | | | |

Based on the results shown in Table 2, Experimental Examples 1 to 7 and Comparative Experimental Examples 1 and 2 were evaluated as to removal rate, selectivity ratio, and dishing. Evaluation results were as follows:

First, Experimental Examples 1 to 7, in which complexing agents were used, showed a significant increase in copper film removal rate, compared to Comparative Experimental Examples 1 and 2.

Second, Experimental Examples 1 to 7, in which polyvinylpyrrolidone (PVP) as the surface protective agent was used, showed a significant increase in silicon oxide film removal rate, compared to Comparative Experimental Examples 1 and 2.

Third, in Experimental Examples 1 to 7, the copper film removal rate increased with increasing content of iminodiacetic acid (IDA) as the complexing agent, and dishing of the copper film decreased with increasing content of ammonium dodecyl benzene sulfonate (ADBS) as the surface protective agent.

For these reasons, Experimental Examples 1 to 7 showed a good selectivity ratio, compared to Comparative Experimental Examples 1 and 2.

Comparative Experimental Example 2 showed increased dishing due to a low content of benzotriazole (BTA) as the corrosion inhibitor, despite exhibiting an increased copper film removal rate.

### Examples 8 to 11 and Comparative Examples 3 to 5

Slurry compositions for polishing a copper barrier layer were prepared according to the formulations shown in Table 3. The slurry compositions were prepared by varying the particle size of colloidal silica and the content of ADBS as the surface protective agent.

In all compositions, the content of colloidal silica was fixed at 15 wt %. In addition, 0.05 wt % of BTA was used as a heterocyclic compound, 0.1 wt % of AA was used as an organic acid, 0.2 wt % of PVP was used as a surface protective agent, 0.2 wt % of KOH was used as a pH adjuster, and 1.0 wt % of KNO₃ was used as a nitrogen compound.

TABLE 3

| | Particle | Heterocyclic | | | | | | | | | |
|---|---|---|---|---|---|---|---|---|---|---|---|
| | size of | compound | | Organic acid | | | | Surface protective agent | | | |
| | silica | | Cont. | | Cont. | | Cont. | | Cont. | | Cont. |
| | (nm) | Mat. | (wt %) | Mat. | (wt %) | Mat. | (wt %) | Mat. | (wt %) | Mat. | (wt %) |
| Comp. | 35 | BTA | 0.05 | IDA | 0.1 | AA | 0.06 | ADBS | 0.05 | PVP | 0.2 |
| Example | | | | | | | | | | | |
| 3 | | | | | | | | | | | |
| Comp. | 60 | BTA | 0.05 | IDA | 0.1 | AA | 0.06 | ADBS | 0.05 | PVP | 0.2 |
| Example | | | | | | | | | | | |
| 4 | | | | | | | | | | | |
| Example | 80 | BTA | 0.05 | IDA | 0.1 | AA | 0.06 | ADBS | 0.05 | PVP | 0.2 |
| 8 | | | | | | | | | | | |
| Example | 90 | BTA | 0.05 | IDA | 0.1 | AA | 0.06 | ADBS | 0.05 | PVP | 0.2 |
| 9 | | | | | | | | | | | |
| Comp. | 100 | BTA | 0.05 | IDA | 0.1 | AA | 0.06 | ADBS | 0.05 | PVP | 0.2 |
| Example | | | | | | | | | | | |
| 5 | | | | | | | | | | | |
| Example | 90 | BTA | 0.05 | IDA | 0.1 | AA | 0.06 | ADBS | 0.1 | PVP | 0.2 |
| 10 | | | | | | | | | | | |
| Example | 90 | BTA | 0.05 | IDA | 0.1 | AA | 0.06 | ADBS | 0.3 | PVP | 0.2 |
| 11 | | | | | | | | | | | |

### Experimental Examples 8 to 11 and Comparative Experimental Examples 3 to 5

Removal rate, selectivity ratio, and defect density were measured for each of the slurry compositions of Examples 8 to 11 and Comparative Examples 3 to 5 and results are presented in Table 4 as Experimental Examples 8 to 11 and Comparative Experimental Examples 3 to 5.

Defect density was measured using an AIT-XP+ system (KLA-Tencor Ltd.) with a light source having a spot size of 10 μm.

TABLE 4

| | Removal rate | | | Selectivity | | |
|---|---|---|---|---|---|---|
| | (Å/min) | | | ratio | | |
| | | | Silicon | Silicon | | Defect |
| | | | oxide | oxide | Cu/ | density |
| | Cu | TaN | film | film/TaN | TaN | (n) |
| Comparative | 97 | 260 | 296 | 1.14 | 0.37 | 24 |
| Experimental | | | | | | |
| Example 3 | | | | | | |
| Comparative | 105 | 287 | 430 | 1.50 | 0.37 | 38 |
| Experimental | | | | | | |
| Example 4 | | | | | | |
| Experimental | 146 | 290 | 720 | 2.48 | 0.50 | 35 |
| Example 8 | | | | | | |
| Experimental | 150 | 300 | 711 | 2.37 | 0.50 | 37 |
| Example 9 | | | | | | |
| Comparative | 175 | 382 | 757 | 1.98 | 0.46 | 119 |
| Experimental | | | | | | |
| Example 5 | | | | | | |
| Experimental | 161 | 318 | 842 | 2.65 | 0.51 | 27 |
| Example 10 | | | | | | |
| Experimental | 163 | 337 | 852 | 2.53 | 0.48 | 23 |
| Example 11 | | | | | | |

From the results shown in Table 4, it can be seen that increase in particle size results in increase in defect density, despite proving increase in removal rate. Comparative Experimental Examples 3 and 4, in which the particle size of colloidal silica was 70 nm or less, exhibited a significantly reduced removal rate for both the copper film and the oxide film, leading to increased process time and reduced productivity.

Additionally, it can be seen that defect density decreases with increasing content of ammonium dodecyl benzene sulfonate (ADBS) as the surface protective agent.

### Examples 12 to 18 and Comparative Examples 6 and 7

Slurry compositions for polishing a copper barrier layer were prepared according to the formulations shown in Table 5.

In all compositions, colloidal silica having a particle size of 90 nm was used as abrasive particles and the content of the colloidal silica was fixed at 15 wt %. In all compositions, KOH was used as a pH adjuster and KNO₃ was used as a nitrogen compound, each in an amount of 0.5 wt %. In addition, 0.2 wt % of ascorbic acid was used as an antioxidant.

TABLE 5

| | Particle | Heterocyclic | | | | | | | | | |
|---|---|---|---|---|---|---|---|---|---|---|---|
| | size of | compound | | Organic acid | | | | Surface protective agent | | | |
| | silica | | Cont. | | Cont. | | Cont. | | Cont. | | Cont. |
| | (nm) | Mat. | (wt %) | Mat. | (wt %) | Mat. | (wt %) | Mat. | (wt %) | Mat. | (wt %) |
| Example | 90 | BTA | 0.1 | | | AA | 0.06 | | | PVP | 0.15 |
| 12 | | | | | | | | | | | |
| Example | 90 | BTA | 0.1 | IDA | 0.1 | AA | 0.06 | ADBS | 0.1 | PVP | 0.2 |
| 13 | | | | | | | | | | | |
| Example | 90 | BTA | 0.1 | IDA | 0.1 | AA | 0.06 | ADBS | 0.3 | PVP | 0.2 |
| 14 | | | | | | | | | | | |
| Example | 90 | BTA | 0.1 | IDA | 0.1 | AA | 0.06 | ADBS | 0.5 | PVP | 0.2 |
| 15 | | | | | | | | | | | |
| Example | 90 | BTA | 0.1 | IDA | 0.1 | AA | 0.06 | ADBS | 0.5 | PVP | 0.3 |
| 16 | | | | | | | | | | | |
| Example | 90 | BTA | 0.1 | IDA | 0.5 | AA | 0.06 | ADBS | 0.5 | PVP | 0.3 |
| 17 | | | | | | | | | | | |
| Example | 90 | BTA | 0.1 | IDA | 1.0 | AA | 0.06 | ADBS | 0.5 | PVP | 0.3 |
| 18 | | | | | | | | | | | |
| Comp. | 90 | BTA | 0.1 | | | | | | | | |
| Example | | | | | | | | | | | |
| 6 | | | | | | | | | | | |
| Comp. | 90 | BTA | 0.02 | | | | | | | | |
| Example | | | | | | | | | | | |
| 7 | | | | | | | | | | | |

BTA: Benzotriazole
IDA: Iminodiacetic acid
AA: Acetic acid
ADBS: Ammonium dodecyl benzene sulfonate
PVP: Polyvinylpyrrolidone

### Experimental Examples 12 to 18 and Comparative Experimental Examples 6 and 7

Removal rate, selectivity ratio, and dishing were measured for each of the slurry compositions of Examples 12 to 18 and Comparative Examples 6 and 7 and results are presented in Table 6 as Experimental Examples 12 to 18 and Comparative Experimental Examples 6 and 7.

TABLE 6

| | Removal rate | | | Selectivity | Selectivity | Dishing |
|---|---|---|---|---|---|---|
| | (Å/min) | | | ratio | ratio | (Å) |
| | Cu | TaN | Ox | Ox/TaN | Cu/TaN | 1-1 μm |
| Experimental | 185 | 370 | 887 | 2.40 | 0.50 | 39 |
| Example 12 | | | | | | |
| Experimental | 191 | 376 | 960 | 2.55 | 0.51 | 31 |
| Example 13 | | | | | | |
| Experimental | 215 | 378 | 972 | 2.57 | 0.57 | 23 |
| Example 14 | | | | | | |
| Experimental | 233 | 382 | 968 | 2.53 | 0.61 | 19 |
| Example 15 | | | | | | |
| Experimental | 240 | 380 | 1140 | 3.00 | 0.63 | 19 |
| Example 16 | | | | | | |
| Example 17 | 252 | 368 | 1080 | 2.93 | 0.68 | 18 |
| Experimental | 254 | 379 | 1130 | 2.98 | 0.67 | 21 |
| Example 18 | | | | | | |
| Comparative | 127 | 309 | 586 | 1.90 | 0.41 | 75 |
| Experimental | | | | | | |
| Example 6 | | | | | | |
| Comparative | 149 | 347 | 680 | 1.96 | 0.43 | 128 |
| Experimental | | | | | | |
| Example 7 | | | | | | |

Based on the results shown in Table 6, Experimental Examples 12 to 18 and Comparative Experimental Examples 6 and 7 were evaluated as to removal rate, selectivity ratio, and dishing. Evaluation results were as follows:

First, Experimental Examples 12 to 18, in which complexing agents were used, showed a significant increase in copper film removal rate, compared to Comparative Experimental Examples 6 and 7.

Second, Experimental Examples 12 to 18, in which polyvinylpyrrolidone (PVP) as the surface protective agent was used, showed a significant increase in silicon oxide film removal rate, compared to Comparative Experimental Examples 6 and 7.

Third, in Experimental Examples 12 to 18, the copper film removal rate increased with increasing content of iminodiacetic acid (IDA) as the complexing agent, and dishing of the copper film decreased with increasing content of ammonium dodecyl benzene sulfonate (ADBS) as the surface protective agent.

For these reasons, Experimental Examples 12 to 18 showed a good selectivity ratio, compared to Comparative Experimental Examples 6 and 7.

Comparative Experimental Example 7 showed increased dishing due to a low content of benzotriazole (BTA) as the corrosion inhibitor, despite exhibiting an increased copper film removal rate.

### Examples 19 to 22 and Comparative Examples 8 to 10

Slurry compositions for polishing a copper barrier layer were prepared according to the formulations shown in Table 7.

The slurry compositions were prepared by varying the particle size of colloidal silica and the content of ADBS as a surface protective agent.

In all compositions, the content of the colloidal silica was fixed at 15 wt %, 0.05 wt % of BTA was used as a heterocyclic compound, 0.1 wt % of AA was used as an organic acid, 0.02 wt % of PVP was used as a surface protective agent, 0.2 wt % of KOH was used as a pH adjuster, and 1.0 wt % of KNO₃ was used as a nitrogen compound.

TABLE 7

| | Particle | Heterocyclic | | | | | | | | | |
|---|---|---|---|---|---|---|---|---|---|---|---|
| | size of | compound | | Organic acid | | | | Surface protective agent | | | |
| | silica | | Cont. | | Cont. | | Cont. | | Cont. | | Cont. |
| | (nm) | Mat. | (wt %) | Mat. | (wt %) | Mat. | (wt %) | Mat. | (wt %) | Mat. | (wt %) |
| Comp. | 35 | BTA | 0.05 | IDA | 0.1 | AA | 0.06 | ADBS | 0.05 | PVP | 0.2 |
| Example | | | | | | | | | | | |
| 8 | | | | | | | | | | | |
| Comp. | 60 | BTA | 0.05 | IDA | 0.1 | AA | 0.06 | ADBS | 0.05 | PVP | 0.2 |
| Example | | | | | | | | | | | |
| 9 | | | | | | | | | | | |
| Example | 80 | BTA | 0.05 | IDA | 0.1 | AA | 0.06 | ADBS | 0.05 | PVP | 0.2 |
| 19 | | | | | | | | | | | |
| Example | 90 | BTA | 0.05 | IDA | 0.1 | AA | 0.06 | ADBS | 0.05 | PVP | 0.2 |
| 20 | | | | | | | | | | | |
| Comp. | 100 | BTA | 0.05 | IDA | 0.1 | AA | 0.06 | ADBS | 0.05 | PVP | 0.2 |
| Example | | | | | | | | | | | |
| 10 | | | | | | | | | | | |
| Example | 90 | BTA | 0.05 | IDA | 0.1 | AA | 0.06 | ADBS | 0.1 | PVP | 0.2 |
| 21 | | | | | | | | | | | |
| Example | 90 | BTA | 0.05 | IDA | 0.1 | AA | 0.06 | ADBS | 0.3 | PVP | 0.2 |
| 22 | | | | | | | | | | | |

### Experimental Examples 19 to 22 and Comparative Experimental Examples 8 to 10

Removal rate, selectivity ratio, and defect density were measured for each of the slurry compositions of Examples 19 to 22 and Comparative Examples 8 to 10 and results are presented in Table 8 as Experimental Examples 19 to 22 and Comparative Experimental Examples 8 to 10.

Defect density was measured using an AIT-XP+ system (KLA-Tencor Ltd.) with a light source having a spot size of 10 μm.

TABLE 8

| | Removal rate | | | Selectivity | | Defect |
|---|---|---|---|---|---|---|
| | (Å/min) | | | ratio | | density |
| | Cu | TaN | Ox | Ox/TaN | Cu/TaN | (n) |
| Comparative | 115 | 310 | 348 | 1.12 | 0.37 | 27 |
| Experimental | | | | | | |
| Example 8 | | | | | | |
| Comparative | 125 | 338 | 510 | 1.51 | 0.37 | 41 |
| Experimental | | | | | | |
| Example 9 | | | | | | |
| Experimental | 172 | 341 | 846 | 2.48 | 0.50 | 47 |
| Example 19 | | | | | | |
| Experimental | 178 | 354 | 956 | 2.70 | 0.50 | 46 |
| Example 20 | | | | | | |
| Comparative | 209 | 452 | 891 | 1.97 | 0.46 | 135 |
| Experimental | | | | | | |
| Example 10 | | | | | | |
| Experimental | 187 | 376 | 994 | 2.64 | 0.50 | 39 |
| Example 21 | | | | | | |
| Experimental | 194 | 397 | 1007 | 2.54 | 0.49 | 28 |
| Example 22 | | | | | | |

Based on the results shown in Table 8, Experimental Examples 19 to 22 and Comparative Experimental Examples 8 to 10 were evaluated as to removal rate, selectivity ratio, and defect density. Evaluation results were as follows:

It was confirmed that increase in particle size of colloidal silica leads to increase in removal rate, but also results in increase in defect density. In particular, Comparative Examples 8 and 9, in which the particle size of colloidal silica was 70 nm or less, exhibited a significantly reduced removal rate with respect to both the copper film and the oxide film, leading to increased process time and reduced productivity.

Additionally, it was confirmed that defect density decreases with increasing content of ammonium dodecyl benzene sulfonate (ADBS) as the surface protective agent.

Similar results were observed for colloidal silica contents of 13% and 15%, thus confirming reproducibility.

Although some embodiments have been described herein, it should be understood that these embodiments are provided for illustration only and are not to be construed in any way as limiting the present invention, and that various modifications, changes, alterations, and equivalent embodiments can be made by those skilled in the art without departing from the spirit and scope of the invention. The scope of the present invention should be defined by the appended claims and equivalents thereto.

1. A CMP slurry composition for polishing a copper barrier layer, comprising: abrasive particles: a heterocyclic compound; a nitrogen compound; an organic acid; a surface protective agent; an antioxidant; a pH adjuster; and the balance of deionized water.

2. The CMP slurry composition according to claim 1, wherein the abrasive particles comprise colloidal silica in which nanoscale silica particles are stably dispersed in a solvent without sedimentation.

3. The CMP slurry composition according to claim 2, wherein the abrasive particles are present in an amount of 13 wt % to 15 wt % in the slurry composition.

4. The CMP slurry composition according to claim 3, wherein the abrasive particles have a particle size of 75 nm to 95 nm.

5. The CMP slurry composition according to claim 1, wherein the heterocyclic compound contains at least two nitrogen atoms and comprises at least one selected from the group consisting of 1,2,4-H-triazole, 5-methylbenzotriazole, tetrazole, imidazole, 1,2-dimethylimidazole, benzotriazole (BTA), 1H-benzotriazole acetonitrile, and piperazine.

6. The CMP slurry composition according to claim 1, wherein the nitrogen compound comprises at least one selected from the group consisting of potassium nitrate (KNO₃), nitric acid (HNO₃), ammonium nitrate (NH₄NO₃), iron nitrate (Fe(NO₃)₂), and copper nitrate (Cu(NO₃)₂).

7. The CMP slurry composition according to claim 6, wherein the nitrogen compound is present in an amount of 0.1 wt % to 10 wt % in the slurry composition.

8. The CMP slurry composition according to claim 1, wherein the organic acid comprises:
i) at least one carboxylic acid selected from the group consisting of citric acid, glutaric acid, malic acid, maleic acid, oxalic acid, phthalic acid, succinic acid, tartaric acid, and acetic acid; and
ii) at least one amino acid selected from the group consisting of nitrilotriacetic acid (NTA), iminodiacetic acid (IDA), methyl iminodiacetic acid (MIDA), hydroxyethyl iminodiacetic acid (HIDA), diethylenetriamine pentaacetic acid (DTPA), ethylenediamine tetraacetic acid (EDTA), n-hydroxyethyl ethylenediamine tetraacetic acid (HEDTA), methyl ethylenediamine tetraacetic acid (MEDTA), and triethylene tetraamine hexaacetic acid (TTHA).

9. The CMP slurry composition according to claim 8, wherein the organic acid is present in an amount of 0.1 wt % to 3 wt % in the slurry composition.

10. The CMP slurry composition according to claim 1, wherein the surface protective agent comprises: at least one nonionic surface protective agent selected from the group consisting of polyvinyl alcohol (PVA), ethylene glycol (EG), glycerin, polyethylene glycol (PEG), polypropylene glycol (PPG), and polyvinylpyrrolidone (PVP); and at least one anionic surface protective agent selected from the group consisting of ammonium dodecyl benzene sulfonate, ammonium polyoxyethylene alkyl sulfonate, and ammonium polyoxyethylene alkyl aryl sulfonate.

11. The CMP slurry composition according to claim 10, wherein the surface protective agent is present in an amount of 0.3 wt % to 0.8 wt % in the slurry composition.

12. The CMP slurry composition according to claim 1, wherein the antioxidant comprises at least one selected from the group consisting of ascorbic acid, L (+)-ascorbic acid, isoascorbic acid, ascorbic acid derivatives, gallic acid, formamidine sulfinic acid, uric acid, tartaric acid, and cysteine.

13. The CMP slurry composition according to claim 12, wherein the antioxidant is present in an amount of 0.1 wt % to 0.5 wt % in the slurry composition.

14. The CMP slurry composition, wherein the pH adjuster comprises at least one selected from the group consisting of KOH, NH₄OH, NaOH, TMAH, TBAH, and HNO₃.

15. The CMP slurry composition according to claim 14, wherein the slurry composition has a pH of 9 to 12.

16. The CMP slurry composition according to claim 1, wherein a polishing target film comprises: a copper-containing film; a thin barrier film comprising at least one selected from the group consisting of titanium (Ti), tantalum (Ta), ruthenium (Ru), molybdenum (Mo), cobalt (Co), and gold (Au); or an oxide film used as a semiconductor insulating film.

17. The CMP slurry composition according to claim 16, wherein the CMP slurry composition has a polishing selectivity ratio of 1:1 to 4:0.5 to 1 with respect to a tantalum nitride (TaN) film, a silicon oxide film, and a copper (Cu) film.
